(19) United States
(12) Patent Application Publication
(10) Pub. No.: US 2026/0371744 A1
(43) Pub. Date: Nov. 19, 2026

(54) ELECTROSTATIC DISCHARGE DEVICE IN STACKED TRANSISTOR WITH NANOSHEET

(71) Applicant: INTERNATIONAL BUSINESS MACHINES CORPORATION, ARMONK, NY (US)

(72) Inventors: Anindya Nath, Watervliet, NY (US); Lijuan Zou, Albany, NY (US); Robert Gauthier, Williston, VT (US); Masoud Zabihi, Schenectady, NY (US); Tenko Yamashita, Schenectady, NY (US); Brent Alan Anderson, Jericho, VT (US)

(21) Appl. No.: 19/212,575

(22) Filed: May 19, 2025

(51) Int. Cl. H10D 89/60

(52) U.S. Cl. CPC H10D 89/814

(57) ABSTRACT

A semiconductor device can include a passive device having a top portion including a first top doped region and a second top doped region laterally separated by a top gate region, and a frontside contact over at least one of the first top doped region and the second top doped region, and a bottom portion including a first bottom doped region and second bottom doped region laterally separated by a bottom gate region, and a first backside contact and a second backside contact below the first bottom doped region and the second bottom doped region, respectively, and a well region electrically connecting the top portion to the bottom portion, and a logic device adjacent to the passive device and including a middle dielectric isolation (MDI) between a top source/drain region and a bottom source/drain region. A thickness of the well region is greater than a thickness of the MDI.

### BACKGROUND

### Technical Field

The present disclosure generally relates to semiconductors, and more particularly, to electrostatic discharge device in stacked transistors with nanosheet channel structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes include a passive device having a top portion including a first top doped region and a second top doped region laterally separated by a top gate region, and a frontside contact over at least one of the first top doped region and the second top doped region, and a bottom portion including a first bottom doped region and second bottom doped region laterally separated by a bottom gate region, and a first backside contact and a second backside contact below the first bottom doped region and the second bottom doped region, respectively, and a well region electrically connecting the top portion to the bottom portion, and a logic device adjacent to the passive device and including a middle dielectric isolation (MDI) between a top source/drain region and a bottom source/drain region. A thickness of the well region is greater than a thickness of the MDI.

In one embodiment, each of the top portion and the bottom portion further comprises a set of nanosheet channels extended horizontally across a gate.

In one embodiment, the semiconductor device is an electrostatic discharge device (ESD).

In one embodiment, the first top doped region and the second top doped region are doped with an N-type dopant, and the first bottom doped region and the second bottom doped region are doped with a P-type dopant.

In one embodiment, the first top doped region and the second top doped region are doped with a P-type dopant, and the first bottom doped region and the second bottom doped region are doped with an N-type dopant.

In one embodiment, the semiconductor device includes a back end of line (BEOL) over the top passive device and the top logic device, and a carrier wafer over the BEOL.

In one embodiment, the semiconductor device is a laterally extended P+ doped region/P-well/N+ doped region diode or a P+ doped region/N-well/N+ doped region diode.

In one embodiment, the semiconductor device is a laterally extended NPN bipolar junction with P-well contact, or a PNP bipolar junction with N-well contact.

In one embodiment, the well region is a silicon region doped with a P-type dopant or an N-type dopant.

In one embodiment, the logic device further comprises a top logic gate region and a bottom logic gate region isolated by the MDI.

In one embodiment, the first bottom doped region and the second bottom doped region are aligned at a same vertical height as the bottom source/drain region.

In one embodiment, the semiconductor device includes a gate contact over the top gate region, and an interlayer dielectric over the passive device and the logic device.

In one embodiment, the logic device further includes a top logic portion and a bottom logic portion, the top logic portion includes the top source/drain region, and the bottom logic portion includes the bottom source/drain region.

In one embodiment, the top logic portion further includes a frontside via connecting the top source/drain region to a frontside of the semiconductor device.

In one embodiment, at least one of the top logic portion and the bottom logic portion is a transistor.

In one embodiment, the top logic portion and the bottom logic portion are field-effect transistors (FET).

According to an embodiment, a method for fabrication of a semiconductor device includes forming a passive device including forming a top portion having a first top doped region and a second top doped region laterally separated by a top gate region, and a frontside contact over at least one of the first top doped region and the second top doped region, and forming a bottom portion including forming a first bottom doped region and second bottom doped region laterally separated by a bottom gate region, and forming a first backside contact and a second backside contact below the first bottom doped region and the second bottom doped region, respectively, and forming a well region electrically connecting the top portion to the bottom portion, and forming a logic device adjacent to the passive device and including a middle dielectric isolation (MDI) between a top source/drain region and a bottom source/drain region. A thickness of the well region is greater than a thickness of the MDI.

According to an embodiment, a semiconductor device includes a passive device including a top device and a bottom device stacked over the top device, and a first well region electrically connecting the top device to the bottom device, and a logic device including a top transistor and a bottom transistor stacked over the top transistor. A thickness of a dielectric isolation layer between the top transistor and the bottom transistor is less than a thickness of the well region.

In one embodiment, each of the passive device and the logic device further includes a set of nanosheet channels extended horizontally across a gate.

In one embodiment, the semiconductor device includes a back end of line (BEOL) over the top device and the top transistor, and a carrier wafer over the BEOL.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate schematically an ESD device operation during the normal circuit operation voltage range, ESD operating window during an ESD event, and the failure region.

FIG. 1C illustrates a conventional planar semiconductor device with shallow trench isolation.

FIGS. 1D-1E illustrate circuitry of the semiconductor device shown in FIG. 1C.

FIG. 1F illustrates an I-V curve of the semiconductor device shown in FIG. 1C.

FIGS. 2A-2B illustrate conventional electrostatic discharge devices with shallow trench isolation.

FIG. 3A illustrates a semiconductor device, in accordance with some embodiments.

FIG. 3B illustrates a semiconductor device formed by bonding flow, in accordance with some embodiments.

FIG. 4A illustrates a lateral diode, in accordance with some embodiments.

FIG. 4B illustrates a lateral bipolar junction, in accordance with some embodiments.

FIG. 4C illustrates a stacked field-effect transistor of the semiconductor device, in accordance with some embodiments.

FIGS. 4D-4E illustrates circuitry of the semiconductor device shown in FIG. 4A and FIG. 4B, respectively.

FIGS. 4F-4G illustrates I-V graphs of the semiconductor device shown in FIG. 4A and FIG. 4B, respectively.

FIG. 5 illustrates a semiconductor device after the growing the first half of the nanosheet stack, in accordance with some embodiments.

FIG. 6 illustrates the semiconductor device after the implantation of the passive device, in accordance with some embodiments.

FIG. 7 illustrates the semiconductor device after the removal of the OPL, in accordance with some embodiments.

FIG. 8 illustrates the semiconductor device after the removal of the hard mask, in accordance with some embodiments.

FIG. 9 illustrates the semiconductor device after the formation of the OPL, in accordance with some embodiments.

FIG. 10 illustrates the semiconductor device after the formation of a high-Ge SiGe layer, in accordance with some embodiments.

FIG. 11 illustrates the semiconductor device after the removal of portions of the high-Ge SiGe layer, in accordance with some embodiments.

FIG. 12 illustrates the semiconductor device after the removal of organic planarization layer, in accordance with some embodiments.

FIG. 13 illustrates the semiconductor device after the formation of the second half of the nanosheet stack, in accordance with some embodiments.

FIG. 14 illustrates the semiconductor device after the formation of the etch stop layer, in accordance with some embodiments.

FIG. 15 illustrates the semiconductor device after the formation of gate hard masks, in accordance with some embodiments.

FIG. 16 illustrates the semiconductor device after the formation of dummy gates, in accordance with some embodiments.

FIG. 17 illustrates the semiconductor device after the removal of the high-Ge SiGe layer, in accordance with some embodiments.

FIG. 18 illustrates the semiconductor device after the formation of the inner spacer and recession of the nanosheet, in accordance with some embodiments.

FIG. 19 illustrates the semiconductor device after the formation of the sacrificial placeholders, in accordance with some embodiments.

FIG. 20 illustrates the semiconductor device after the formation of the bottom source/drain region, in accordance with some embodiments.

FIG. 21 illustrates the semiconductor device after the recession of the bottom source/drain region, in accordance with some embodiments.

FIG. 22 illustrates the semiconductor device after the formation of interlayer dielectric, in accordance with some embodiments.

FIG. 23 illustrates the semiconductor device after the recessing of the interlayer dielectric, in accordance with some embodiments.

FIG. 24 illustrates the semiconductor device after the formation of the doped region, in accordance with some embodiments.

FIG. 25 illustrates the semiconductor device after the formation of the top doped regions, in accordance with some embodiments.

FIG. 26 illustrates the semiconductor device after the formation of the interlayer dielectric, in accordance with some embodiments.

FIG. 27 illustrates the semiconductor device after the middle of line processes, and the back end of line processes, in accordance with some embodiments.

FIG. 28 illustrates a block diagram of a method 2800 for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter can be combined with elements of different embodiments.

In foundry technology, designing electrostatic discharge (ESD) protection devices require addressing the diverse needs of typical input/output (I/O) configurations. These devices should meet stringent requirements to ensure robust protection against voltage spikes caused by ESD events while maintaining compatibility with the I/O types commonly used in advanced semiconductor technologies. The main categories of ESD devices for such applications include vertical bipolar transistors, lateral bipolar transistors, thyristors (also known as silicon-controlled rectifiers, SCRs), and power supply clamps. Each of these device types plays a distinct role in safeguarding sensitive circuits, depending on the application and performance requirements.

Vertical bipolar transistors are widely used in ESD protection circuits due to their ability to handle high current densities efficiently. Their vertically stacked structure allows current to flow perpendicularly to the plane of the substrate, enabling compact device layouts that can dissipate significant amounts of energy during an ESD event. These devices are typically implemented as NPN or PNP transistors, depending on the specific requirements of the circuit. Vertical bipolars are particularly advantageous in applications requiring high-speed protection and efficient integration into multi-layered semiconductor devices.

Lateral bipolar transistors offer an alternative approach, with current flowing parallel to the surface of the substrate. This lateral configuration provides greater flexibility in layout design and is often used in planar processes where space constraints or integration with other planar devices are priorities. Lateral bipolars are commonly employed in scenarios where high-speed response and precise control of the ESD protection mechanism are critical. Their planar nature also makes them well-suited for integration in standard CMOS technologies.

Thyristors, such as NPNP or PNPN configurations, are another component of ESD protection strategies. These devices operate as controlled switches that latch into a low-resistance state when triggered, allowing them to conduct large amounts of current away from sensitive circuit areas. Thyristors are especially effective for applications requiring high-current handling capabilities, making them suitable for protecting power-intensive I/O lines or circuits prone to high-voltage transients. The inherent current-limiting and latching characteristics of thyristors ensure that the device can respond effectively to sudden surges without impacting normal circuit operation.

Power supply clamps are one category of ESD protection devices, typically designed using circuits with wide field-effect transistors (FETs). These clamps act as voltage regulators during ESD events, providing a low-resistance path between power rails to shunt excess energy safely. The use of wide FETs in these clamps allows for higher current-carrying capacity, ensuring that power rails are effectively protected from overvoltage conditions. Power supply clamps are critical for safeguarding the integrity of the power distribution network within semiconductor devices, especially in high-density integrated circuits where stable power delivery is essential.

Together, these device types provide a comprehensive set of tools for addressing the diverse challenges posed by ESD protection in foundry technologies. By combining vertical and lateral bipolar transistors, thyristors, and power supply clamps, designers can create robust protection schemes tailored to the unique requirements of modern semiconductor applications, ensuring reliable performance and longevity of the devices.

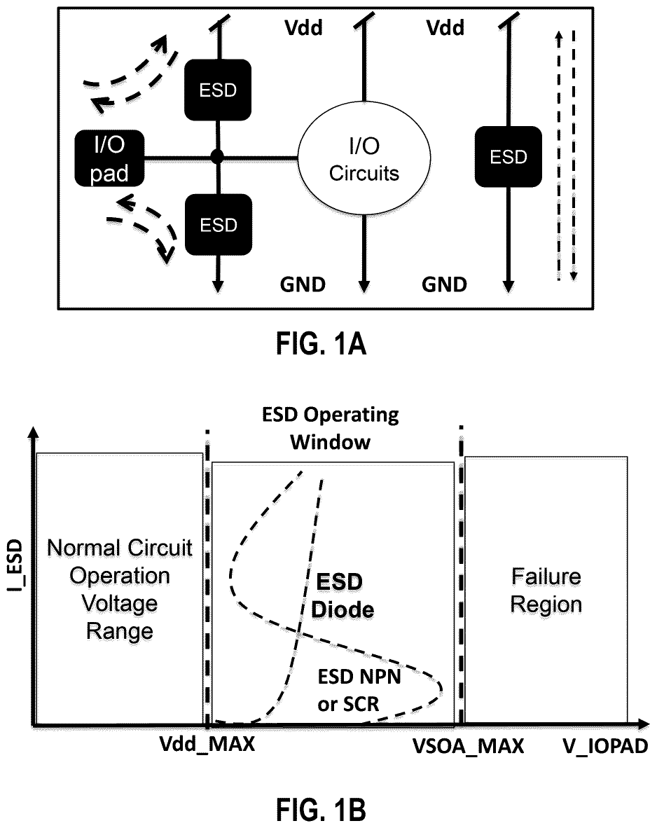

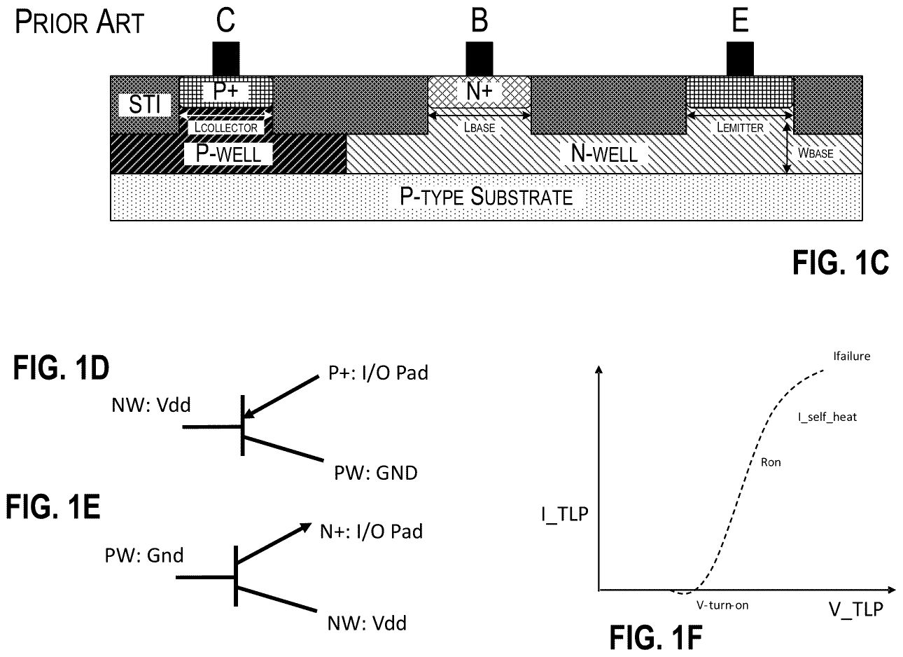

FIGS. 1A-1B illustrate schematically an ESD device operation during the normal circuit operation voltage range, ESD operating window during an ESD event, and the failure region. FIG. 1C illustrates a conventional planar semiconductor device with shallow trench isolation. FIGS. 1D-1E illustrate circuitry of the semiconductor device shown in FIG. 1C. FIG. 1F illustrates an I-V curve of the semiconductor device shown in FIG. 1C. A Planar CMOS shallow trench isolation (STI)-bound PNP transistor operates by enabling controlled current flow from the emitter to the collector through the base. This type of bipolar junction transistor (BJT) uses STI regions for electrical isolation, ensuring that the current paths are confined to specific regions within the transistor. The transistor is designed for compatibility with planar CMOS processes, making it suitable for high-density integrated circuits. In a PNP transistor, the emitter is a heavily doped P-type region that injects holes into the N-type base when a forward bias is applied across the base-emitter junction. The base, being lightly doped and thinner than the emitter, allows the majority of the injected holes to diffuse through it without significant recombination. These holes are then collected by the moderately doped P-type collector, completing the current flow through the transistor. The operation depends on maintaining the correct forward bias voltage across the base-emitter junction, typically requiring the base to be slightly negative relative to the emitter.

The STI regions are insulating trenches that surround the emitter, base, and collector. The trenches are filled with a dielectric material, such as silicon dioxide, to isolate the transistor electrically from adjacent devices in the circuit. The isolation prevents leakage currents and minimizes parasitic effects that could interfere with the transistor's operation. The STI ensures that the current flow remains within the intended regions of the transistor, enhancing its efficiency and reliability. Contacts for the emitter, base, and collector are positioned on the surface of the semiconductor device, allowing external connections to the transistor. The contacts are connected through interconnect layers, which are carefully aligned to the respective regions of the transistor. The STI provides a physical barrier, helping to ensure that these connections do not short-circuit or interfere with neighboring components.

The functionality of this transistor extends to its integration within CMOS processes, allowing it to coexist with other planar CMOS devices. The planar design, combined with STI isolation, enhances its performance by reducing parasitic capacitance and ensuring that the device operates effectively within the confines of a densely packed semiconductor layout. This configuration makes the STI-bound PNP transistor, or its NPN counterpart, a versatile choice for various applications, including analog circuits, mixed-signal designs, and ESD protection.

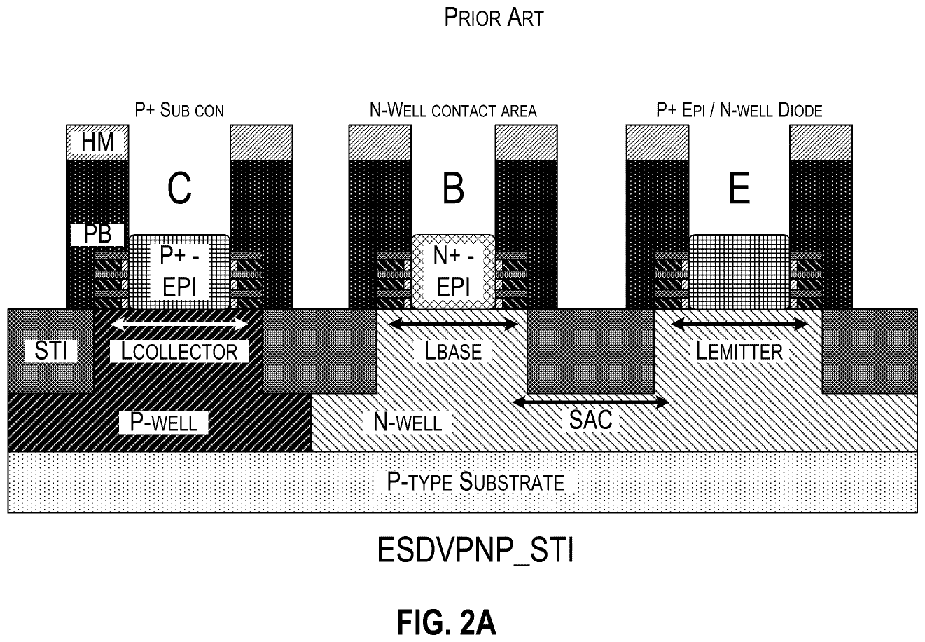

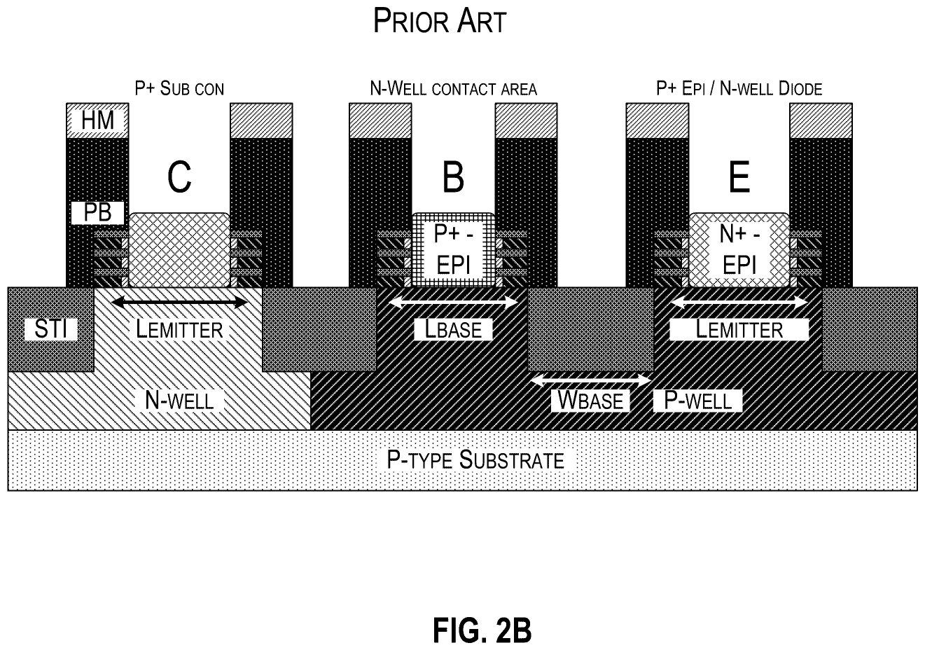

FIGS. 2A-2B illustrate conventional electrostatic discharge devices with shallow trench isolation. An ESD VPNP (Vertical PNP) and ESD VNPN (Vertical NPN) transistor with STI commonly referred to as ESDVPNP_STI and ESDVNPN_STI, are specialized bipolar junction transistors designed for electrostatic discharge (ESD) protection. Such devices leverage their vertical structure and STI isolation to efficiently handle high transient currents during ESD events while maintaining compactness and electrical isolation in semiconductor circuits.

The ESDVPNP_STI operates by facilitating current flow from a heavily doped P-type emitter, through a lightly doped N-type base, to a moderately doped P-type collector. During an ESD event, a sudden voltage spike forward-biases the base-emitter junction, allowing holes from the P-type emitter to be injected into the N-type base. The holes diffuse through the base and are collected by the P-type collector. The vertical configuration directs the current perpendicular to the plane of the substrate, which enables the device to conduct large amounts of current while minimizing the space required. The STI surrounding the emitter, base, and collector provides electrical isolation, ensuring that the current flow is confined to the intended path and does not interfere with adjacent devices.

Similarly, the ESDVNPN_STI operates with electrons as the primary charge carriers. In this case, a heavily doped N-type emitter injects electrons into a lightly doped P-type base when the base-emitter junction is forward-biased during an ESD event. The electrons traverse the base and are collected by the moderately doped N-type collector. The vertical current flow, combined with the isolation provided by STI, ensures efficient conduction and effective dissipation of the high transient currents caused by the ESD pulse. By electrically isolating the emitter, base, and collector from adjacent components, STI prevents leakage currents and parasitic interactions that could degrade the performance of the device. The isolation also allows the ESDVPNP_STI and ESDVNPN_STI to be integrated seamlessly into dense semiconductor layouts without compromising reliability.

During an ESD event, these devices act as current conduits, rapidly transitioning from a high-impedance state to a low-impedance state to safely dissipate the surge energy. The vertical configuration ensures that the conduction path can handle large currents efficiently, minimizing the risk of thermal or structural damage to the device. Once the ESD event subsides, the devices return to their high-impedance state, ready to protect the circuit again in future events. Both the ESDVPNP_STI and ESDVNPN_STI have the ability to manage high transient currents in a compact, isolated structure makes them suitable for use in advanced integrated circuits, ensuring robustness and reliability across a wide range of applications.

Disclosed is a semiconductor device with stacked structure that is designed to optimize electronic function and integration by clearly delineating N-doped and P-doped regions across different layers. The semiconductor device can include a passive device section, e.g., an electrostatic discharge section, and a logic device section, e.g., nanosheet field-effect transistor, Such a separation enhances the overall performance of the device and provides scalability in its functional applications. The device includes two main active layers: the top device layer and the bottom device layer. The top device layer is characterized by P-doped regions, and conversely, the bottom device layer contains N-doped regions. This arrangement of doping in separate layers minimizes electrical interference and improves the efficiency of carrier flow, which is crucial for the device's performance. Positioned between these two layers is an intermediate semiconductor layer that is integral to both the structural and functional integrity of the device. Notably thicker than the conventional middle of line dielectric isolation (MDI) layer used in many semiconductor devices, this intermediate layer provides robust mechanical support and enhances the electrical connectivity between the top and bottom device layers.

The intermediate layer can facilitate effective transfer of charge carriers between the N-doped and P-doped regions. Its substantial thickness, compared to the MDI layer, ensures improved isolation of the device layers, significantly reducing crosstalk and leakage currents and thereby enhancing the device's overall performance. The device is fabricated through a process that ensures precision in layering and doping accuracy. Initially, the bottom device layer is deposited on a suitable substrate, where N-doped regions are established using techniques like ion implantation or diffusion. Following this, the intermediate semiconductor layer is applied over the bottom device layer using methods such as epitaxial growth or chemical vapor deposition, ensuring it meets the required thickness and material quality for optimal electrical and structural functionality. The top device layer is then deposited, forming P-doped regions through similar doping processes to achieve the desired P-type characteristics.

The design approach of separating N and P-doped regions into different layers with a robust intermediate semiconductor layer brings several advantages. It allows for higher operational speeds and reduced power consumption due to the enhanced electrical performance facilitated by the segregation of charge carriers into separate layers. The device's reliability has also increased as the thicker intermediate layer provides better physical separation and electrical insulation, which helps in reducing defects and failures associated with doping impurities or electrical shorts. Moreover, such a layered structure makes the device more adaptable for scaling and integration into various microelectronic applications, including processors, memory chips, and specialized sensors.

Accordingly, the teachings herein provide methods and systems of an electrostatic device coupled to nanosheet transistor structures. The techniques described herein may be implemented in a number of ways. Example implementations are provided below with reference to the following figures.

Example Semiconductor Device with ESD in Stacked Transistors with Nanosheet Structure

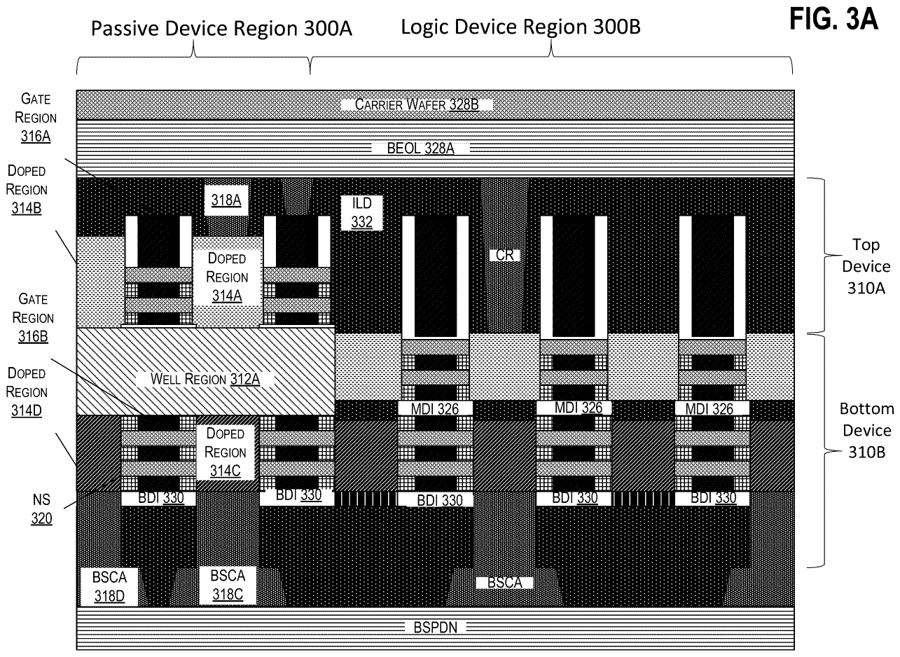

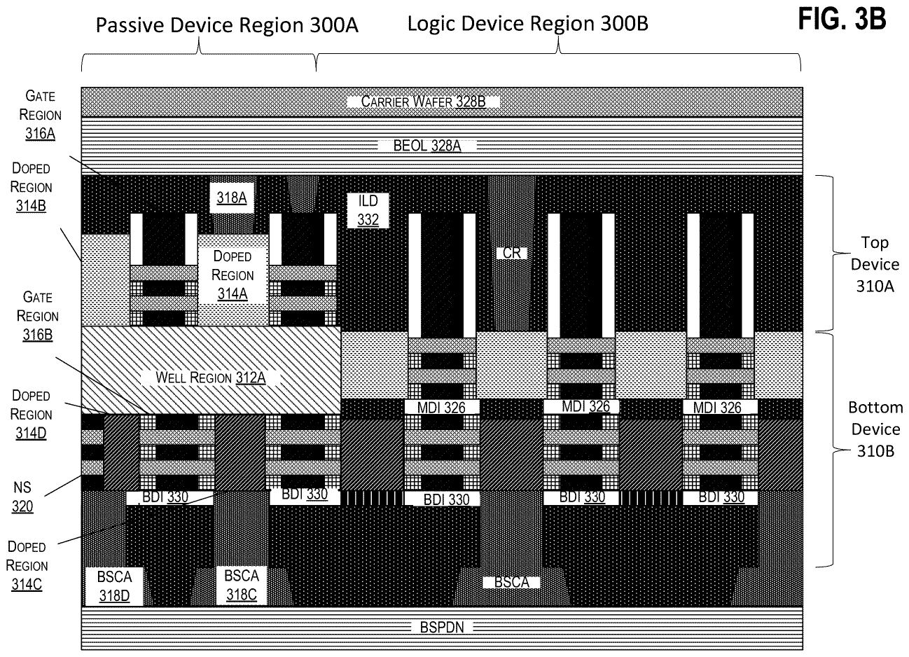

Reference now is made to FIGS. 3A-3B, which are simplified cross-section view of a semiconductor device, consistent with illustrative embodiments. While in FIG. 3A, a monolithic flow is shown in which the top logic device, e.g., top logic portion, and the bottom logic device, e.g., bottom logic portion, are aligned, FIG. 3B depicts a sequential, e.g., bonding flow, in which the top logic device and the bottom logic device are misaligned. FIG. 3A illustrates a semiconductor device formed in a monolithic flow, and FIG. 3B illustrates a semiconductor device formed by bonding flow. The semiconductor device can include a passive device region 300A and a logic device region 300B. The passive device region 300A includes a top device 310A, e.g., a top portion (e.g., device) 310A, a bottom device 310B (e.g., a bottom portion), a well region 312A, gate regions, and doped regions. Adjacent to the passive device is the logic device and is divided into the top logic device and the bottom logic device, separated by the middle dielectric isolation, MDI 326. Both the top and bottom devices incorporate sets of nanosheet channels that extend horizontally across each gate. The channels enhance the electron mobility and overall electrical conductivity of the device.

In some embodiments, the passive device resides alongside one or more logic devices on the same die, allowing both to be manufactured in a unified process flow. In each logic device, the top and bottom doped regions—serving as source and drain—are electrically isolated by dielectric layers. By contrast, in the passive device those same doped regions are tied together via intervening lightly doped silicon sections. Similarly, the gate stacks of the logic device remain separated by a middle dielectric isolation layer, which is composed of insulating material that prevents conduction between vertically stacked gate electrodes. In the passive device, the lightly doped silicon interconnects between the top and bottom regions form a thicker well than the middle dielectric isolation region used in the logic device. The bottom doped regions of both the passive device and logic device share the same vertical position, aligning their lower source and drain terminals. The top doped regions differ, however: in the passive device, they lie at a greater elevation than those in the logic device. Such an offset reflects the passive device's need for a more substantial well region, which accommodates its internal connection between top and bottom doped areas without compromising isolation or performance.

The top device 310A can be structured with a first top doped region 314A, a top gate region 316A, and a frontside contact 318A. The first top doped region 314A is a semiconductor area that has been intentionally infused with impurities, or “doped,” to create either an excess of electrons (N-type) or holes (P-type), enabling it to conduct electricity. The top gate region 316A serves as a control element, modulating current flow through the top device 310A by applying an electric field across the first top doped region 314A. The gating capability allows for selective control over current passage, which is valuable in applications that require switching or modulation of signals. The frontside contact 318A on the top device 310A provides a connection point on the upper surface of the semiconductor device, allowing the top device 310A to interface with external circuitry.

The configuration allows for controlled electron flow and charge distribution. The frontside contact facilitates external electrical connections and enhances signal integrity. Similarly, the backside contacts ground and complete the electrical circuit through the device. The well region, which is thicker than the MDI 326, which is used in the accompanying logic devices, supports the structural integrity of the device and ensures electrical continuity between the top and bottom parts of the passive device, enabling effective charge carrier transport across the semiconductor structure.

The top device 310A can be structured with a second top doped region 314B. The second top doped region 314B is a semiconductor area that has been intentionally infused with impurities, or “doped,” to create either an excess of electrons (N-type) or holes (P-type), enabling it to conduct electricity. The top gate region 316A serves as a control element, modulating current flow through the top device 310A by applying an electric field across the second top doped region 314B. The gating capability allows for selective control over current passage, which is valuable in applications that require switching or modulation of signals.

The bottom device 310B is composed of a first bottom doped region 314C, a bottom gate region 316B, and a first backside contact 318C, e.g., BSCA. The first bottom doped region 314C is created through doping to control the type and flow of charge carriers. The bottom gate region 316B, positioned adjacent to the first bottom doped region 314C, enables control over the current in the bottom device 310B through an applied electric field, facilitating precise modulation of current flow. The first backside contact 318C allows for connection through the lower surface of the semiconductor device, providing an alternate pathway for current flow and enabling more efficient layout and integration within larger circuit structures. Such an arrangement of the frontside contact 318A and the first backside contact 318C provides flexible options for routing and integrating the device into various circuit designs.

The bottom device 310B is composed of a second bottom doped region 314D and a second backside contact 318D. The second bottom doped region 314D is created through doping to control the type and flow of charge carriers. The bottom gate region 316B, positioned adjacent to the second bottom doped region 314D, enables control over the current in the bottom device 310B through an applied electric field, facilitating precise modulation of current flow. The second backside contact 318D allows for connection through the lower surface of the semiconductor device, providing an alternate pathway for current flow and enabling more efficient layout and integration within larger circuit structures.

A well region 312A electrically connects the top device 310A and the bottom device 310B, forming a continuous path for current flow between them. The well region 312A acts as an intermediary layer that can be either an in situ-doped semiconductor layer, e.g., it is doped during fabrication to the desired conductivity, or an implant layer where dopants are implanted after the initial layer formation. The well region 312A supports stable electrical connection between the top device 310A and the bottom device 310B, ensuring consistent performance. In some embodiments, the well region 312A is an N-well, which is lightly doped with N-type impurities, or a P-well, which is lightly doped with a P-type impurities.

The top device 310A and the bottom device 310B can each include nanosheet channels in a gate all around structure, NS 320, that extend horizontally across a gate channel. NS 320 are ultra-thin, planar gate structures that provide control over current flow through the gate channel, improving the switching speed and electrical efficiency of the device. Horizontal extension of the NS 320 allows for improved layout flexibility, helping to minimize the device footprint and enable high-density integration within semiconductor circuits.

In some configurations, one or more of the top device 310A and the bottom device 310B can function as an electrostatic discharge (ESD) device, providing protection against voltage surges. ESD devices can protect sensitive circuitry from damage caused by sudden electrostatic discharge events, which can occur during handling or operation. By integrating ESD functionality, the semiconductor device can act as a safeguard within electronic systems, ensuring that voltage spikes do not impact connected components.

In some embodiments, the top and/or bottom devices can be configured as specific circuit elements, such as bipolar junction transistors (BJTs) or diodes. When one of the devices is configured as a BJT, it provides amplification or switching functionality within the device, with input and output contacts situated at different levels. If configured as a diode, the top device and/or the bottom device can act as a unidirectional current flow controller, with input and output contacts placed on opposite sides of the device to establish a clear directional path for current flow.

The top gate region 316A, and the bottom gate region 316B are positioned adjacent to an active device layer but are electrically isolated from one another. Such an isolation prevents unintended interactions between the gate regions, allowing each device to operate independently and avoiding crosstalk that could interfere with precise control over current flow. This design feature is particularly advantageous in multi-layer semiconductor devices, where independent operation of stacked devices is essential for accurate circuit performance.

Furthermore, the semiconductor device includes distinct doping types for the top and bottom regions. The first top doped region 314A and the second top doped region 314B can be a P-type (N-type) doped region, providing holes as the primary charge carriers, while the first bottom doped region 314C and the second bottom doped region 314D can be an N-type (P-type) doped region, supplying electrons as the primary carriers. The P-N configuration across the top and bottom regions, in conjunction with the well region 312A that electrically connects them, establishes a complementary charge system, allowing for smooth current flow and supporting diverse applications that require both P-type and N-type characteristics.

The semiconductor device is further enhanced with a back end of line, BEOL 328A, over the top passive and logic devices and a carrier wafer 328B over the BEOL 328A, which adds to the mechanical stability and provides additional electrical pathways. In some embodiments, a bottom dielectric isolation, BDI 330 isolates the bottom doped regions from the interlayer dielectric, ILD 332. A spacer can be formed over sidewalls of the channel regions.

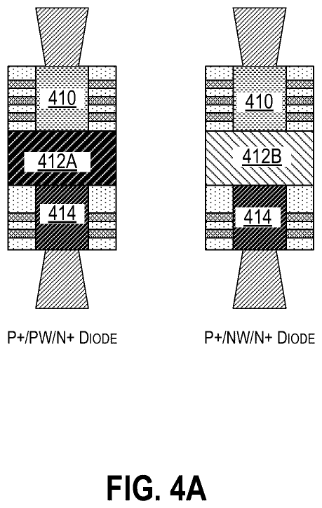

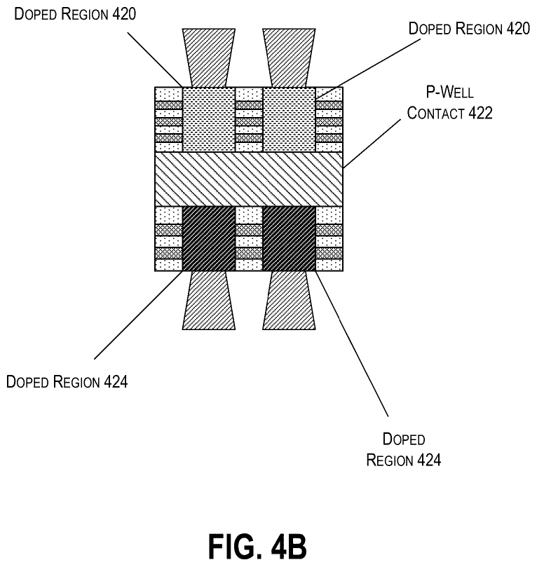

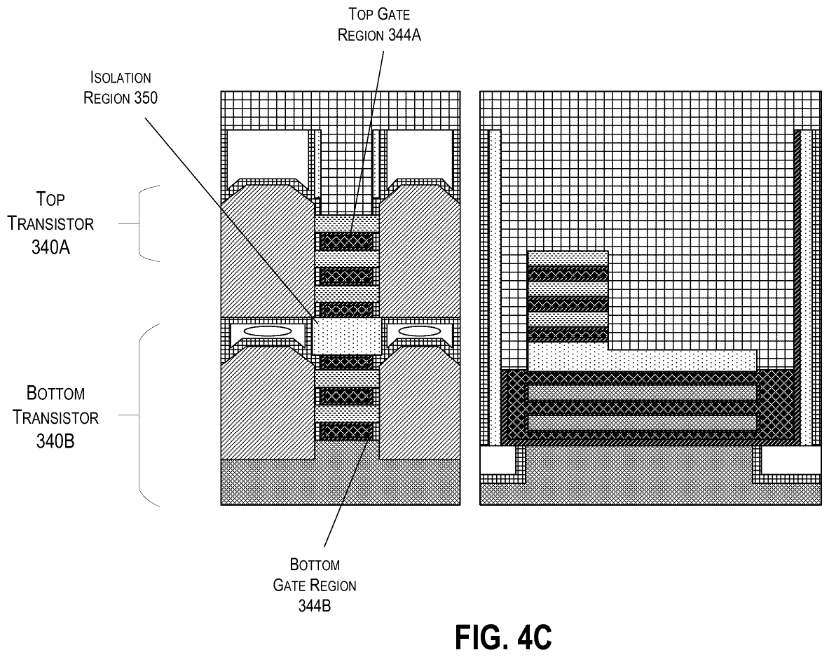

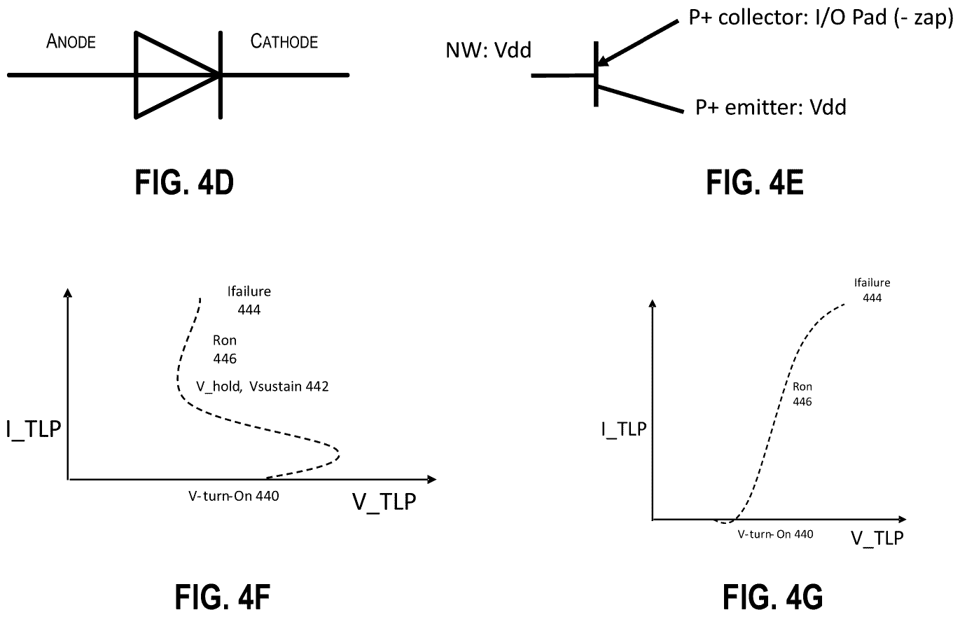

FIG. 4A illustrates a lateral diode, in accordance with some embodiments. In some embodiments, the semiconductor device can function as a vertical ESD diode protecting sensitive circuits from high-voltage spikes associated with ESD events. The vertical ESD diode structure provides a vertically oriented pathway for current flow, allowing it to rapidly conduct excess charge away from vulnerable circuit areas. In this configuration, the device can take one of two forms, either a P+/P-Well/N+ diode, or a P+/N-Well/N+ diode.

In the P+/P-Well/N+ diode configuration, the device comprises a P+ doped region 410, a P-well region 412A, and an N+ region 414. The P+ doped region 410, located at the top of the device, is highly doped with positive charge carriers (holes), while the N+ region 414, positioned at the bottom, is highly doped with negative charge carriers (electrons). The P-well region 412A, which is lightly doped with P-type impurities, serves as an intermediary layer between the P+ and N+ regions. The structure creates a diode with a strong P-N junction between the P-well and N+region, allowing it to act as a unidirectional current path that only becomes conductive under certain voltage conditions. When an ESD event occurs, the diode becomes forward biased, allowing it to conduct current vertically through the structure, thereby safely dissipating the excess charge to protect the connected circuitry. The P+/PW/N+ structure is advantageous in scenarios requiring a lower trigger voltage, as the P-well provides a closer potential alignment with the P+ region, allowing for a faster response during an ESD event.

Alternatively, the passive device can be configured as a P+/N-Well/N+ diode (P+/NW/N+ diode). In this design, the top P+ doped region 410 is paired with an N-well region 412B, which is lightly doped with N-type impurities, positioned between the P+ and N+ regions. The N-well provides a different junction characteristic compared to the P-well, which affects the diode's breakdown voltage and response time. In this case, the P+/NW/N+ structure creates a P-N junction between the P+ region and the N-well, providing a more defined potential barrier and a higher threshold for conduction. When an ESD event generates a high enough voltage, the diode becomes forward biased, allowing current to flow through the device and dissipate the ESD pulse.

Both configurations, whether P+/PW/N+ or P+/NW/N+, provide effective ESD protection by offering a low-resistance path for current when triggered, allowing the device to shunt damaging surges away from sensitive components. The vertical orientation of these ESD diodes enables efficient integration within multi-layer or compact designs, supporting a high degree of layout flexibility while delivering reliable ESD protection. The choice between a P-well or N-well layer allows for tuning of the trigger and breakdown voltages, enabling the passive device to be tailored to specific voltage and protection requirements in various semiconductor applications.

FIG. 4B illustrates a lateral bipolar junction, in accordance with some embodiments. In some embodiments, the passive device can be a lateral NPN bipolar junction transistor (BJT) utilizing a P-well contact. In the lateral NPN BJT, the structure involves the emitter, base, and collector arranged laterally as opposed to the traditional vertical stacking in typical BJTs. The P-well contact acts as the base region. This P-well contact 422 is a section in the semiconductor where p-type doping has been implemented, typically surrounded by n-type material that forms the other two regions: the emitter and the collector. The operation of the transistor begins with the injection of electrons from the n-type emitter into the p-type base region, the P-well. The electrons then travel across the base to reach the n-type collector. The control exerted by the base over the flow of electrons from the emitter to the collector enables the transistor to function as an amplifier or a switch. The semiconductor device can include P-doped region 420, and N-doped region 424 as well.

The P-well contact ensures that the base region can connect externally to the rest of the circuit, allowing for proper biasing during the BJT's operation. The lateral arrangement of the NPN structure along a single plane facilitates easier integration into surface-based semiconductor technologies like CMOS or BiCMOS, which combine bipolar junction transistors and MOSFETs for improved performance. The lateral design of the NPN BJT can reduce parasitic effects by minimizing the depth of the junctions, thereby decreasing parasitic capacitance and enhancing the device's speed. Such a structure can be compatible with planar semiconductor manufacturing processes, allowing for integration with other types of transistors and passive components on the same chip.

FIG. 4C illustrates stacked field effect transistors, in accordance with some embodiments. The semiconductor device includes an integrated logic device, which can include a top transistor 340A and a bottom transistor 340B arranged in a vertical configuration. The structure allows for efficient stacking and compact design while providing distinct functionality between the top and bottom transistors, each with its specific regions and contacts to support electrical isolation and selective control over current flow.

The top transistor 340A in the logic device features a top source/drain region, a top transistor gate region 344A, and a frontside source/drain contact. The top source/drain is a doped area within the top transistor 340A, allowing it to either emit or receive charge carriers based on its specific configuration (N-type or P-type). The top transistor gate region 344A, positioned adjacent to the top source/drain region, functions as the control element for the top transistor 340A, modulating the flow of charge carriers by applying an electric field across the gate. This control capability enables switching behavior in the top transistor 340A. The frontside source/drain contact provides an accessible connection on the upper surface of the semiconductor device, allowing the top transistor 340A to interact with other frontside circuit elements or external components.

The bottom transistor 340B is located below the top transistor 340A and includes a bottom source/drain region, a bottom transistor gate region 344B, and a backside source/drain contact. The bottom source/drain region is a doped region that facilitates current flow, with doping chosen based on the transistor's desired electrical characteristics. The bottom transistor gate region 344B, adjacent to the bottom source/drain region, controls the current flow through the bottom transistor 340B by applying a gate voltage, providing the logic device with the ability to switch states effectively. The backside contact on the bottom transistor 340B is located on the underside of the semiconductor device, providing an alternate pathway for connection, allowing integration with circuitry on the backside and optimizing layout flexibility within complex circuit designs.

An electrically isolating region, e.g., isolating region 350, is positioned between the top and bottom transistors to prevent direct electrical interaction, ensuring that each transistor operates independently. The isolating region 350 can consist of an insulating material or a specific semiconductor structure designed to reduce crosstalk or interference between the two transistors. The presence of the isolating region 350 allows each transistor to maintain its distinct electrical characteristics without interference, supporting stable and reliable operation within the logic device.

In some configurations, the bottom transistor 340B is an n-type field-effect transistor (nFET). As an nFET, the bottom transistor 340B has an N-type doped source/drain region, meaning that it conducts electrons as the primary charge carriers. The nFET configuration provides fast switching speeds and low on-resistance, which is beneficial for logic circuits requiring rapid response times and high efficiency. The nFET's ability to handle higher electron mobility contributes to the overall performance of the semiconductor device, making it particularly suitable for applications where speed and efficiency are critical. The configuration of the top and bottom transistors, with distinct source/drain regions, gate regions, and contact placements, provides a versatile logic device within the semiconductor structure. The combination of a frontside and backside contact layout, along with the isolated transistor operation, allows for efficient integration in advanced circuit designs, enhancing both functionality and spatial efficiency.

FIGS. 4D-4E illustrate a circuitry of the semiconductor device depicted in FIGS. 4A-4B, respectively. FIGS. 4F-4G illustrate an I-V graph of the semiconductor device depicted in FIGS. 4A-4B, respectively. As illustrated in FIGS. 4F-4G, the semiconductor device's regions of operation can be divided into distinct phases: leakage or pre-turn-on, trigger or turn-on, holding or sustaining, and failure. The leakage or pre-turn-on region is the initial phase of the device's operation when it is in a high-impedance state. During this phase, the device conducts only a minimal leakage current, which can be negligible and does not interfere with normal circuit operation. The behavior ensures that the device remains passive and non-disruptive during regular operation, activating only when necessary. The leakage region is influenced by factors such as the quality of the junctions, doping concentrations, and the surrounding isolation structures.

The trigger or turn-on region 440, marks the transition of the device from the high-impedance state to a low-impedance conductive state. This phase occurs when the voltage across the device exceeds the trigger voltage. The trigger voltage is a parameter that defines the threshold at which the device activates to conduct significant current. During this phase, the device begins to conduct current rapidly, responding to an external stimulus such as an ESD event or overvoltage condition. The speed and reliability of this transition are critical for effective protection and performance.

The holding or sustaining region 442 represents the stable operational phase of the device after it has been triggered. In this phase, the device remains in a low-impedance state, conducting current efficiently to dissipate excess energy. The holding or sustaining voltage, often lower than the trigger voltage, ensures that the device remains conductive as long as the external current source persists. This phase is characterized by parameters such as Ron 446, the on-resistance of the device, which determines the voltage drop and power dissipation during conduction. A low Ron value is desirable to minimize energy loss and heat generation. This region is crucial for ensuring the safe dissipation of transient energy without compromising the device's structural integrity.

The failure region 444 occurs when the device exceeds its operational limits, such as the maximum voltage or current it can handle. This phase represents the breakdown or destruction of the device, often due to excessive energy input that surpasses the material or structural limits. In addition to these regions, the device's behavior is influenced by its load capacitance, which represents the capacitance seen by the device in the circuit. Load capacitance affects the device's response time, energy dissipation, and overall performance. A high load capacitance can slow down the device's response, potentially impacting its ability to protect the circuit effectively during fast transients.

### Example Fabrication of A Semiconductor Device in Stacked Transistors With Nanosheet Structure

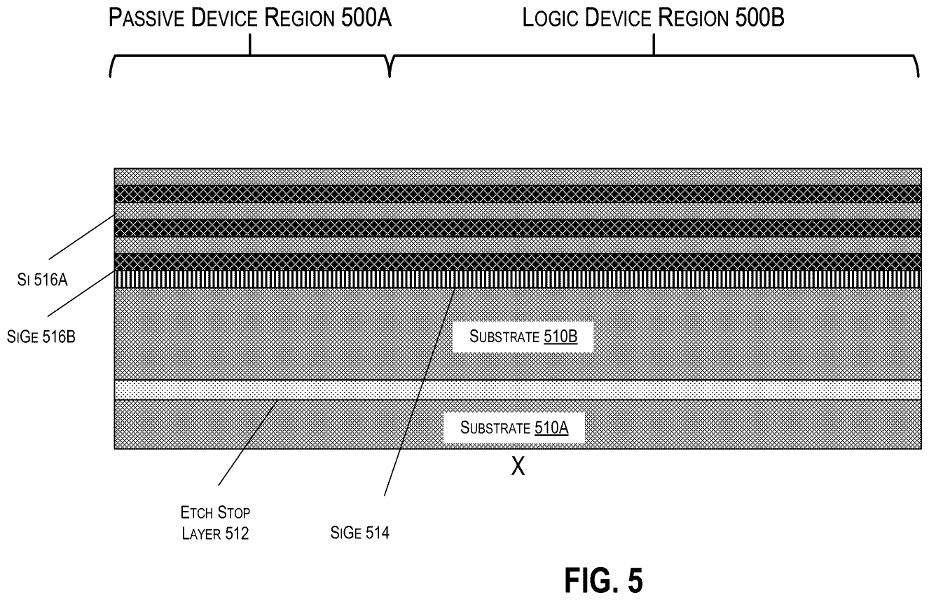

With the foregoing description of an example semiconductor device, it may be helpful to discuss an example process of manufacturing the same. To that end, FIGS. 5-26 illustrate various acts in the manufacture of a semiconductor device, consistent with illustrative embodiments.

Reference now is made to FIG. 5, which is a simplified cross-section view of a semiconductor device, after the preparation of the first half of the sheet stack, consistent with an illustrative embodiment. The semiconductor can include a passive device 500A and a logic device 500B having a first substrate 510A, an etch stop layer 512, a second substrate 510B, a layer of high-Ge SiGe 514, and alternating layers of Si 516A and SiGe 516B.

In the illustrative example depicted in FIG. 5, the semiconductor device is depicted as being on silicon as the first substrate 510A and the second substrate 510B, while it will be understood that other types as the first substrate 510A and the second substrate 510B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 510A and the second substrate 510B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 512 is formed between the first substrate 510A and the second substrate 510B. The etch stop layer 512 can be a thin layer of material incorporated into the structure of the semiconductor device to provide a selective barrier against etching processes, preventing further removal of underlying materials during fabrication. The etch stop layer 512 can enable precise control over the etching depth and help define the desired device dimensions. The etch stop layer 512 can further provide a stopping point for the etching process, ensuring that specific layers or regions are not etched beyond a certain point, leading to accurate patterning and control of critical features. The etch stop layer 512 can create a distinct separation between different layers or components within the device structure, and prevent the undesired etching of underlying layers or materials, enabling the creation of complex, multi-layered structures with well-defined interfaces and boundaries. In some embodiments, the etch stop layer 512 acts as a protective barrier for sensitive or delicate materials to shield such materials from aggressive etchants, preventing damage or degradation during subsequent fabrication steps.

In some embodiments, prior to forming the etch stop layer 512, the first substrate 510A and/or the second substrate 510B is prepared by cleaning and removing any impurities or oxide layers. The etch stop layer 512 is deposited onto the first substrate 510A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 512 can then be selectively etched, stopping at a predetermined depth, while protecting the underlying layers. After the etching process, the remaining photoresist can be removed through stripping techniques. While in some embodiments, SiGe is used to form the etch stop layer 512, in some embodiments, silicon nitride (SiN), silicon oxide (SiO2), or silicon oxynitride (SiON) can be used as the etch stop layer 512.

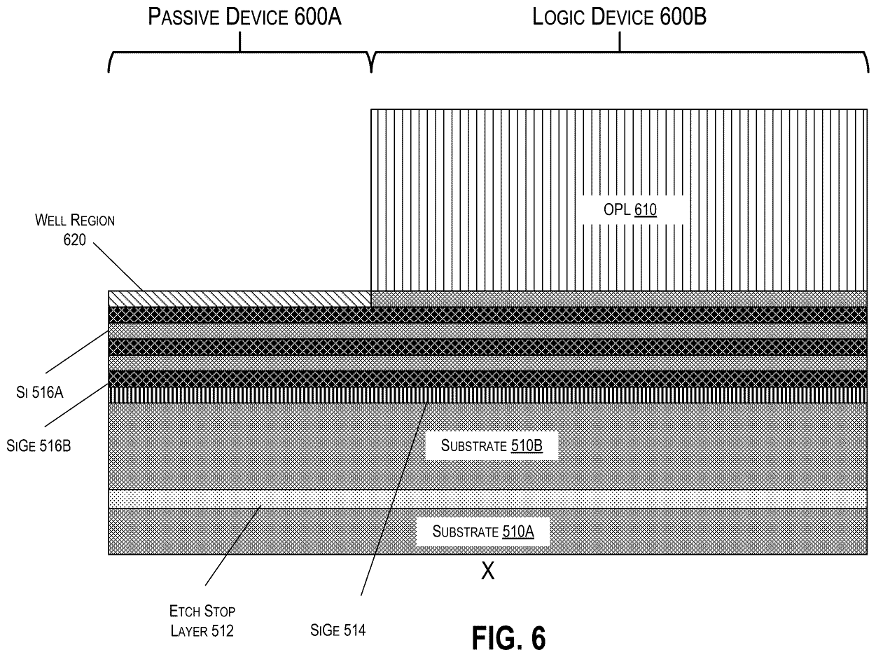

FIG. 6 illustrates the semiconductor device after the implantation of the passive device, in accordance with some embodiments. In some embodiments, an organic planarization layer, OPL 610, is formed over the logic device 600B. The passive device 600A is implanted to form an N-well or a P-well., e.g., well region 620.

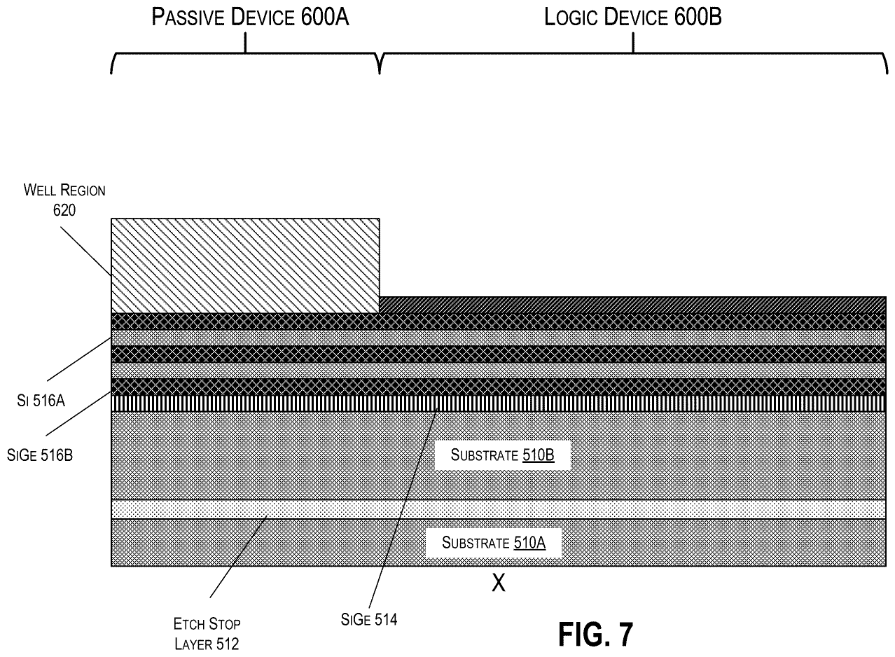

FIG. 7 illustrates the semiconductor device after the removal of the OPL, in accordance with some embodiments. In some embodiments, the OPL is removed, e.g., stripped, and the well region 620 is thickened by growing more epitaxial layer.

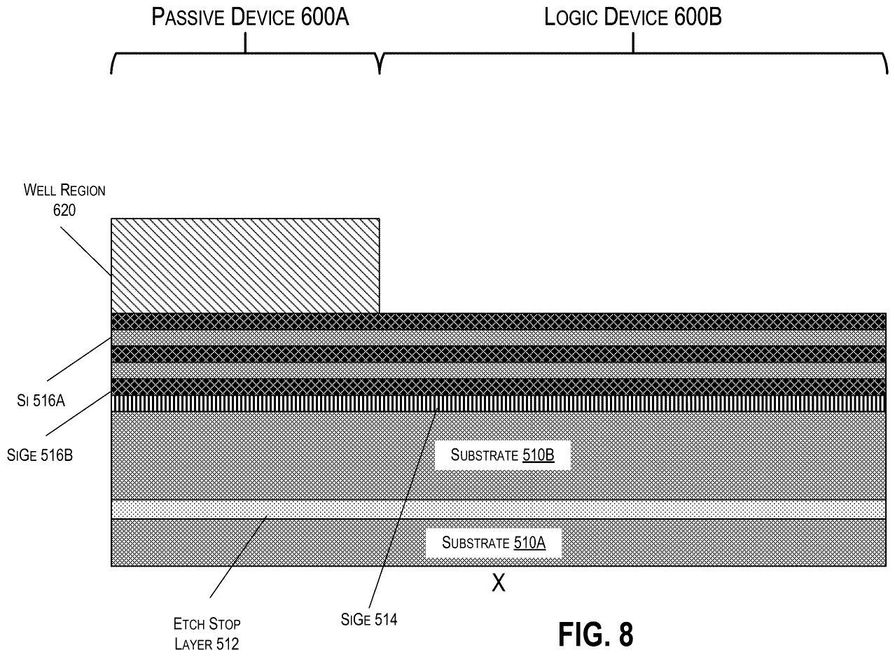

FIG. 8 illustrates the semiconductor device after the removal of the hard mask, in accordance with some embodiments. In some embodiments, the hard mask is removed, e.g., stripped.

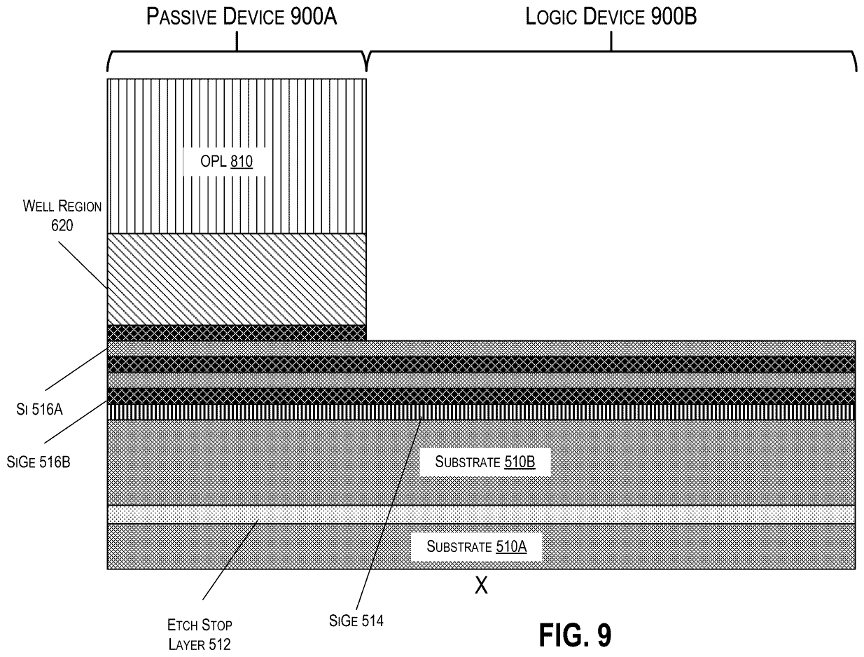

FIG. 9 illustrates the semiconductor device after the formation of the OPL, in accordance with some embodiments. In some embodiments, an OPL 810 is formed over the passive device 900A and the uppermost layer of Si is removed from the logic device 900B.

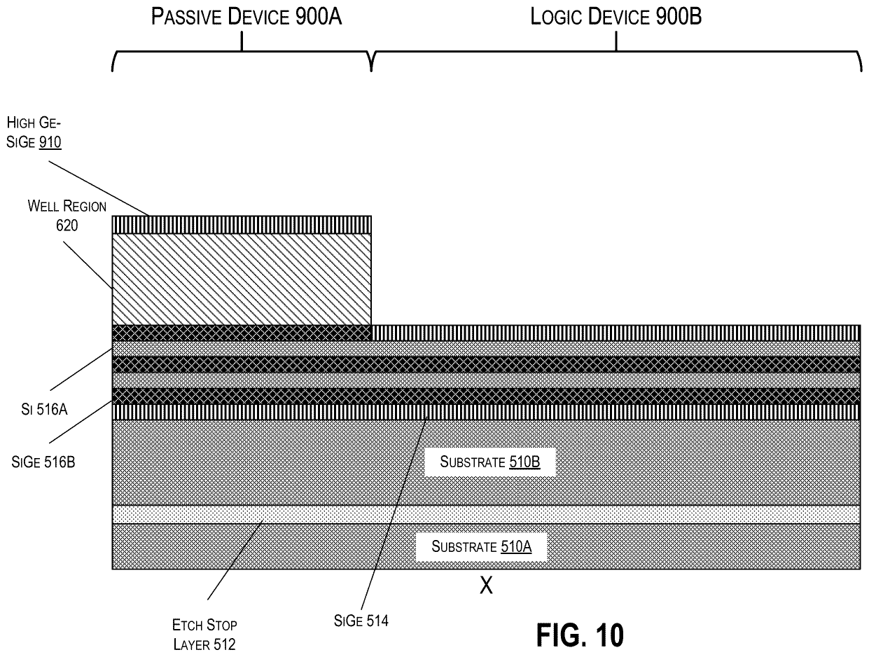

FIG. 10 illustrates the semiconductor device after the formation of a high-Ge SiGe layer, in accordance with some embodiments. In some embodiments, the OPL is removed and a layer of high-Ge SiGe 910 is formed over the semiconductor device.

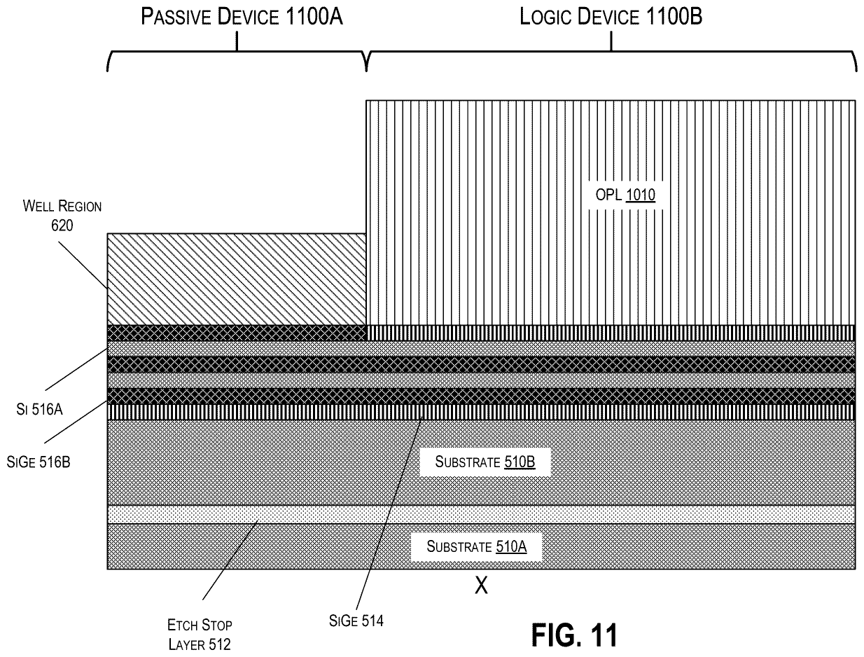

FIG. 11 illustrates the semiconductor device after the removal of portions of the high-Ge SiGe layer, in accordance with some embodiments. In some embodiments, an OPL 1010 is formed over the logic device 1100B and the high Ge-SiGe layer is removed from the passive device 1100A.

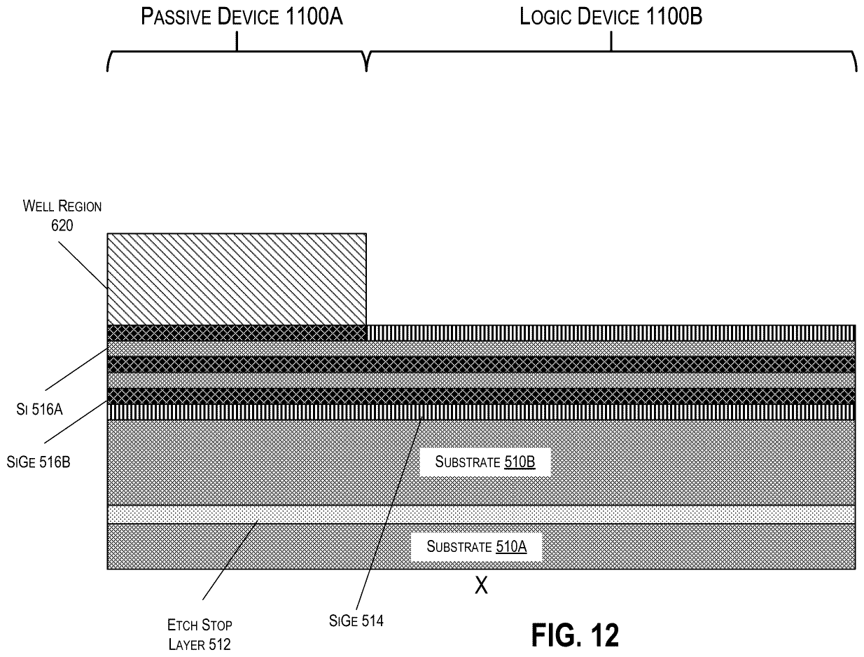

FIG. 12 illustrates the semiconductor device after the removal of organic planarization layer, in accordance with some embodiments. In some embodiments, the OPL is removed from the semiconductor device.

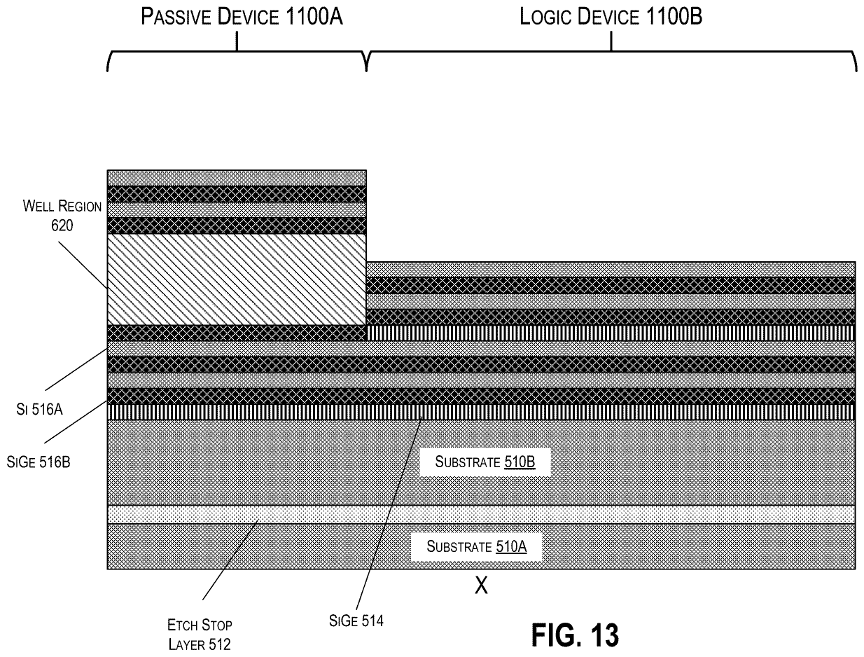

FIG. 13 illustrates the semiconductor device after the formation of the second half of the nanosheet stack, in accordance with some embodiments. In some embodiments, additional layers of Si and SiGe are formed over the semiconductor device.

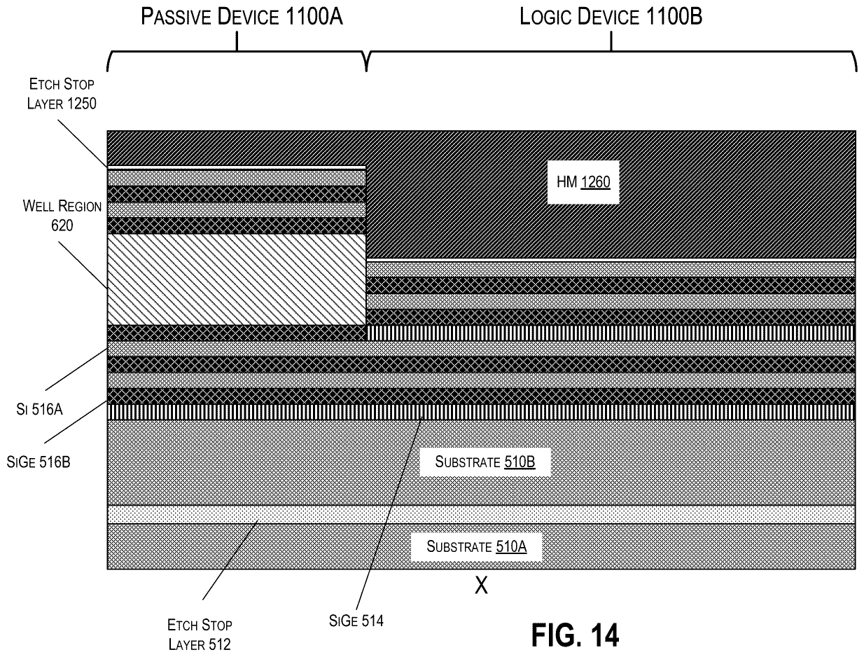

FIG. 14 illustrates the semiconductor device after the formation of the etch stop layer, in accordance with some embodiments. In some embodiments, an etch stop layer is 1250 formed over the semiconductor device, followed by the formation of hard mask, HM 1260.

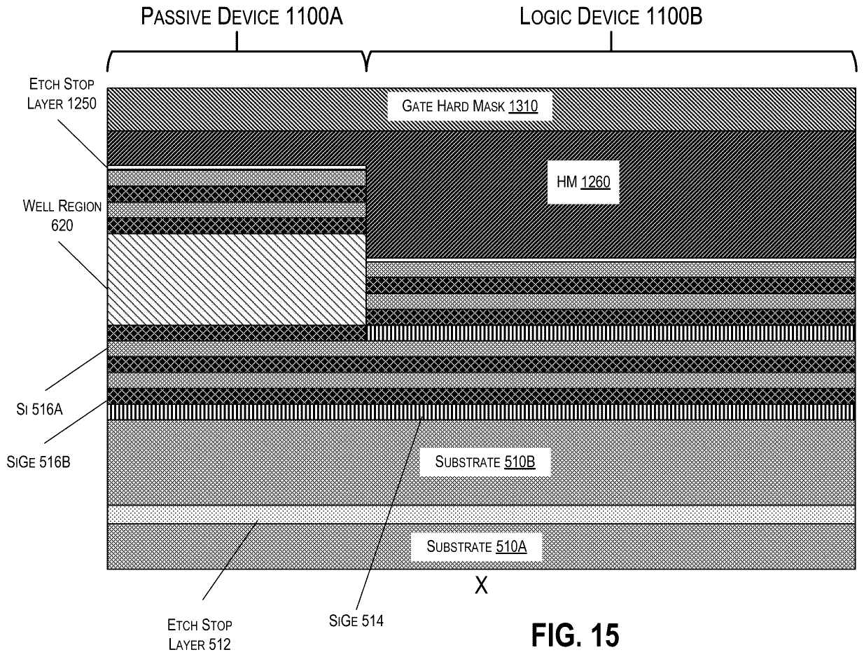

FIG. 15 illustrates the semiconductor device after the formation of gate hard masks, in accordance with some embodiments. In some embodiments, a gate hard mask 1310 is formed over the semiconductor device.

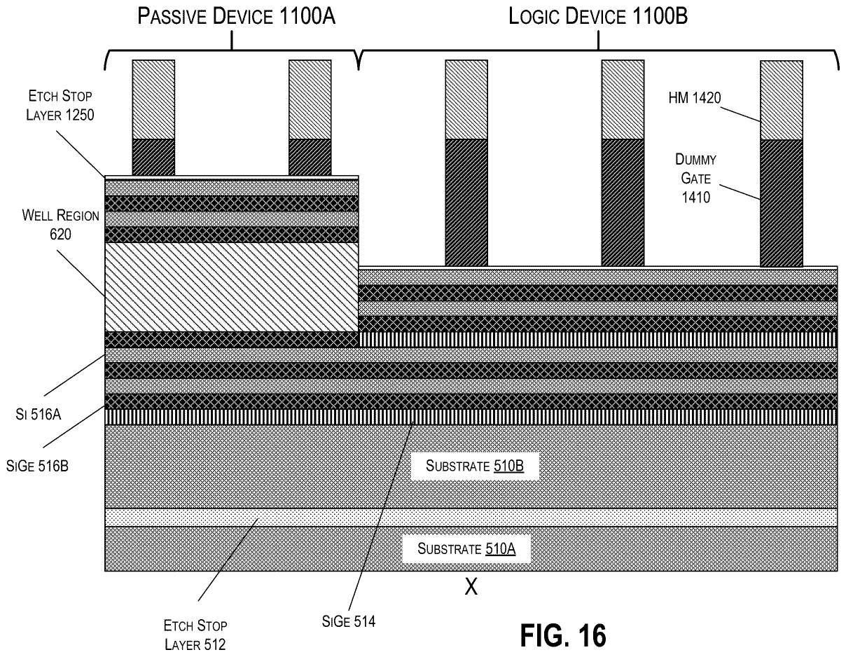

FIG. 16 illustrates the semiconductor device after the formation of dummy gates, in accordance with some embodiments. In some embodiments, stacks of dummy gates 1410 and hard masks, HM 1420, are formed over the semiconductor device.

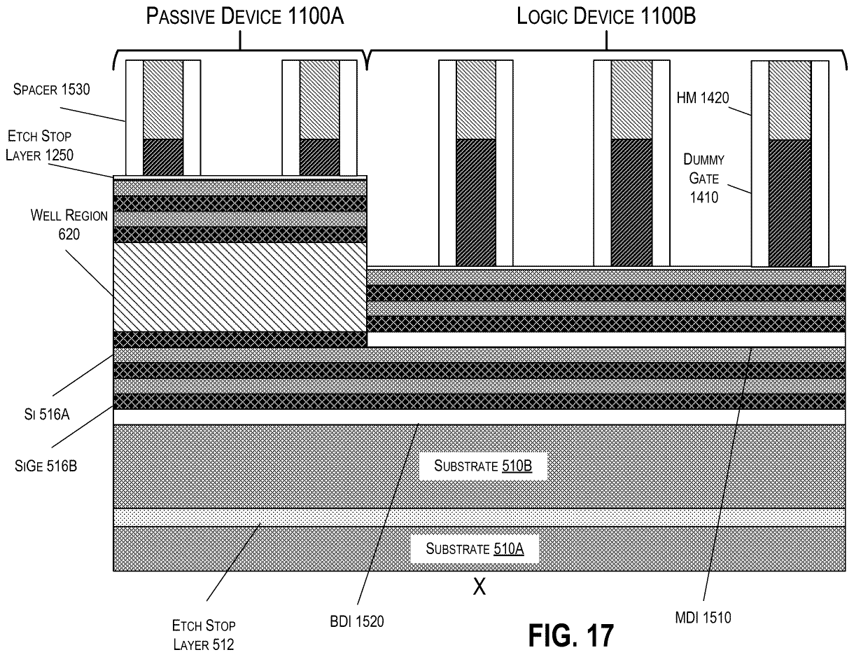

FIG. 17 illustrates the semiconductor device after the removal of the high-Ge SiGe layer, in accordance with some embodiments. In some embodiments, the high-Ge SiGe layer is removed and replaced by a middle dielectric interlayer, MDI 1510, and a bottom interlayer dielectric, BDI 1520. A spacer 1530 can be formed over the sidewalls of the stacks of dummy gates 1410 and HM 1420.

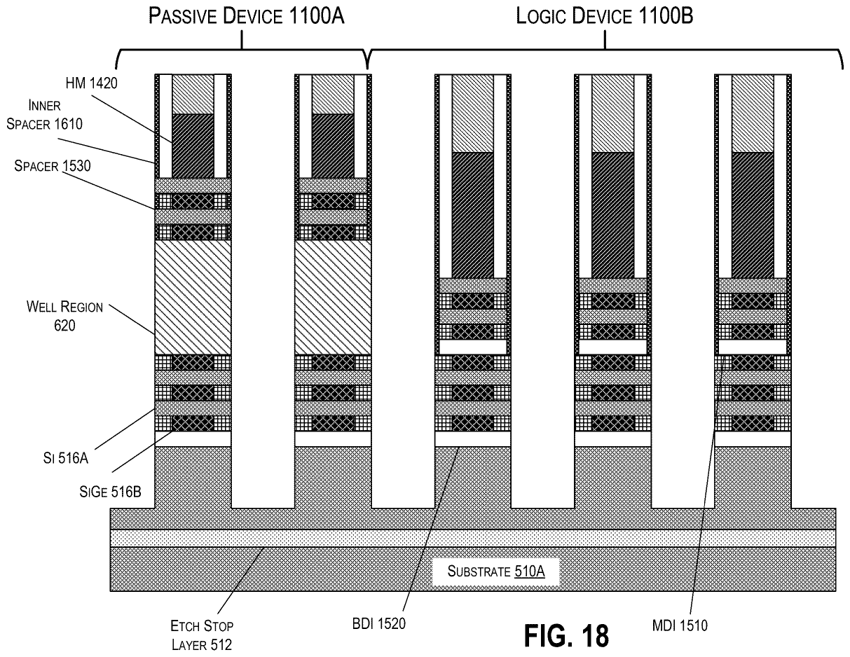

FIG. 18 illustrates the semiconductor device after the formation of the inner spacer and recession of the nanosheet, in accordance with some embodiments. In some embodiments, the top nanosheet is recessed and the SiGe layer is indented. An inner spacer 1610 is formed over the sidewalls of the stacks of dummy gates 1410 and HM 1420.

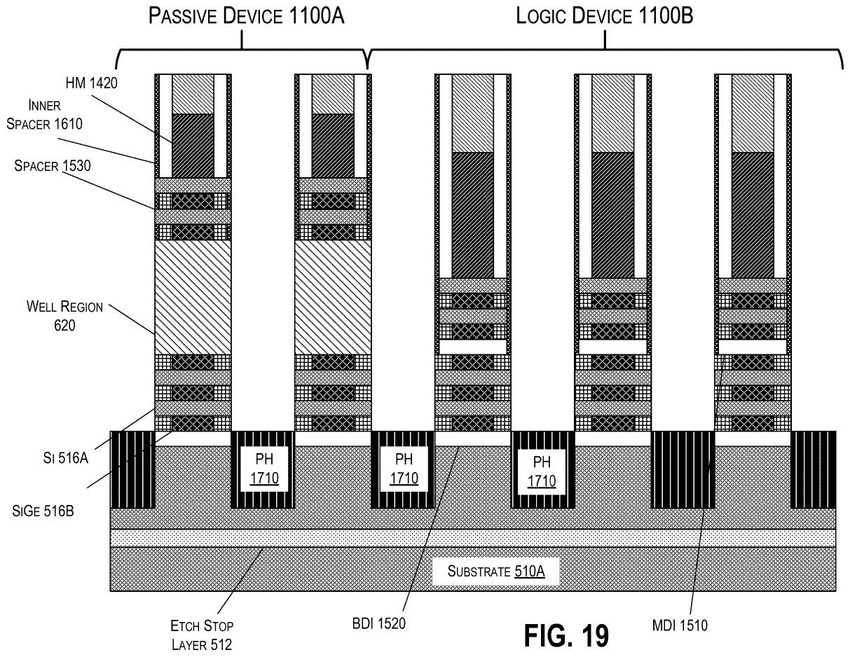

FIG. 19 illustrates the semiconductor device after the formation of the sacrificial placeholders, in accordance with some embodiments. In some embodiments, sacrificial placeholders, PH 1710, are formed between the stacks of dummy gates 1410 and HM 1420.

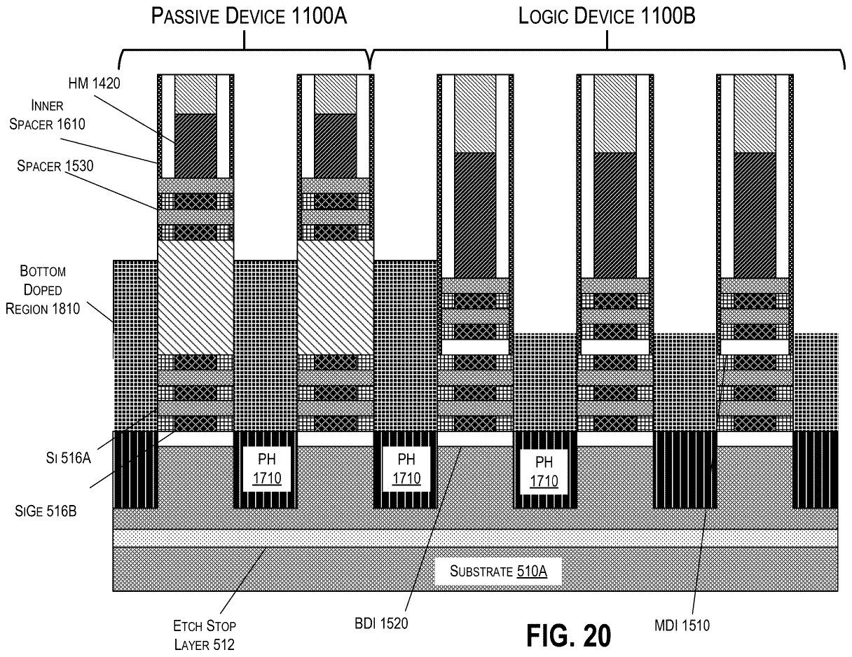

FIG. 20 illustrates the semiconductor device after the formation of the bottom source/drain region, in accordance with some embodiments. In some embodiments, the bottom source/drain regions and/or the bottom doped regions 1810 are formed over the PH 1710.

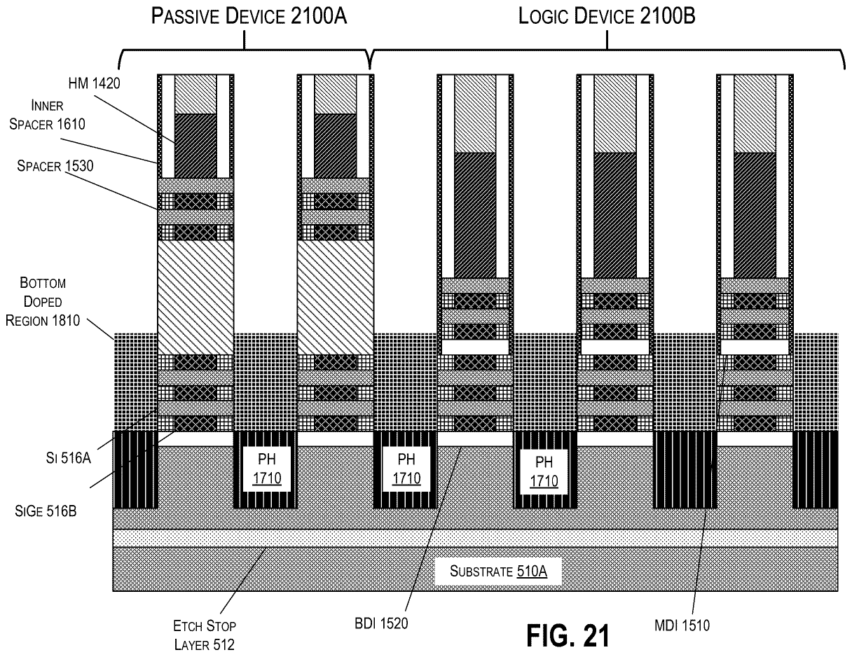

FIG. 21 illustrates the semiconductor device after the recession of the bottom source/drain region, in accordance with some embodiments. In some embodiments, upper portions of the bottom source/drain regions in the passive device 2100A are removed, so the bottom source/drain regions in the passive device 2100A and the logic device 2100B are on the same level.

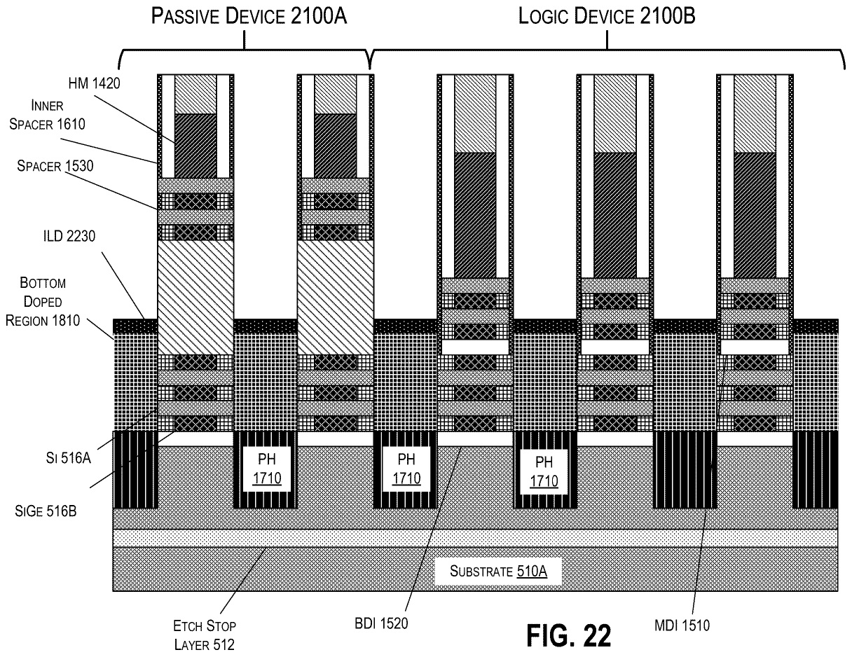

FIG. 22 illustrates the semiconductor device after the formation of interlayer dielectric, in accordance with some embodiments. In some embodiments, the bottom doped regions 1810 are recessed and an ILD 2230 is formed over the bottom doped regions 1810.

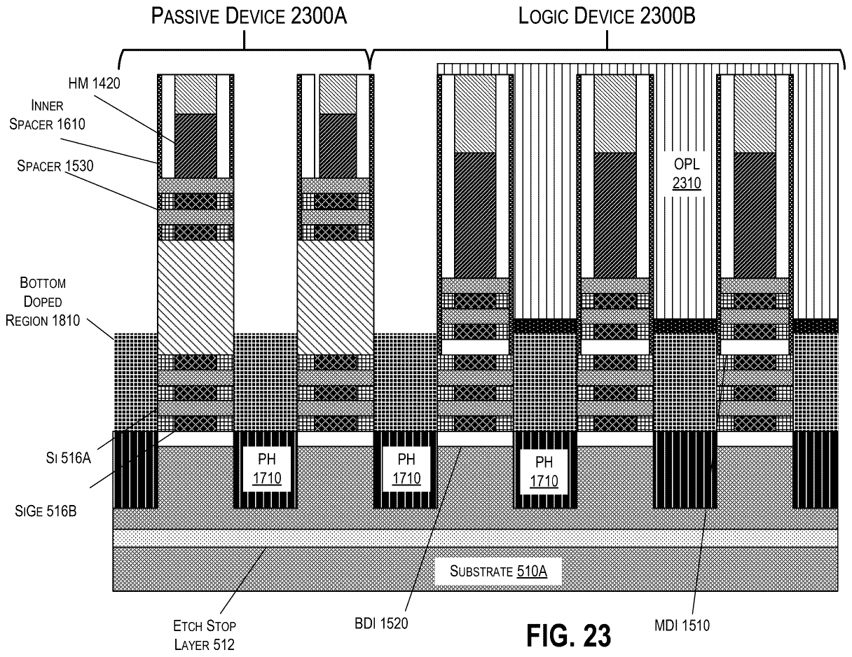

FIG. 23 illustrates the semiconductor device after the recessing of the interlayer dielectric, in accordance with some embodiments. In some embodiments, an OPL 2310 is formed over the logic device 2300B and the ILD 2230 is recessed in the passive device 2300A.

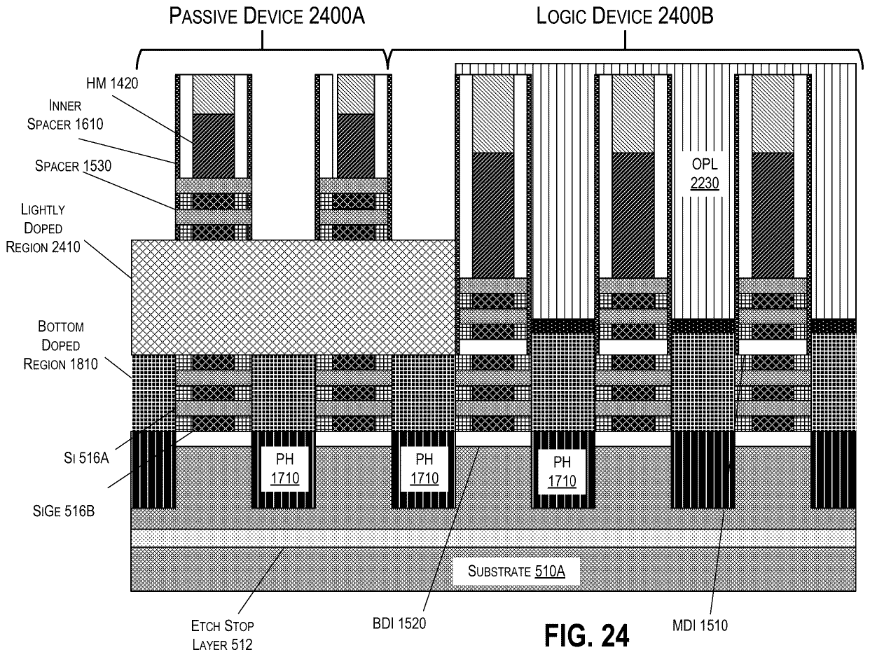

FIG. 24 illustrates the semiconductor device after the formation of the doped region, in accordance with some embodiments. In some embodiments, a lightly doped region 2410 is formed over the bottom doped regions 1810 in the passive device 2400A. An OPL 2310 is formed over the logic device 2400B.

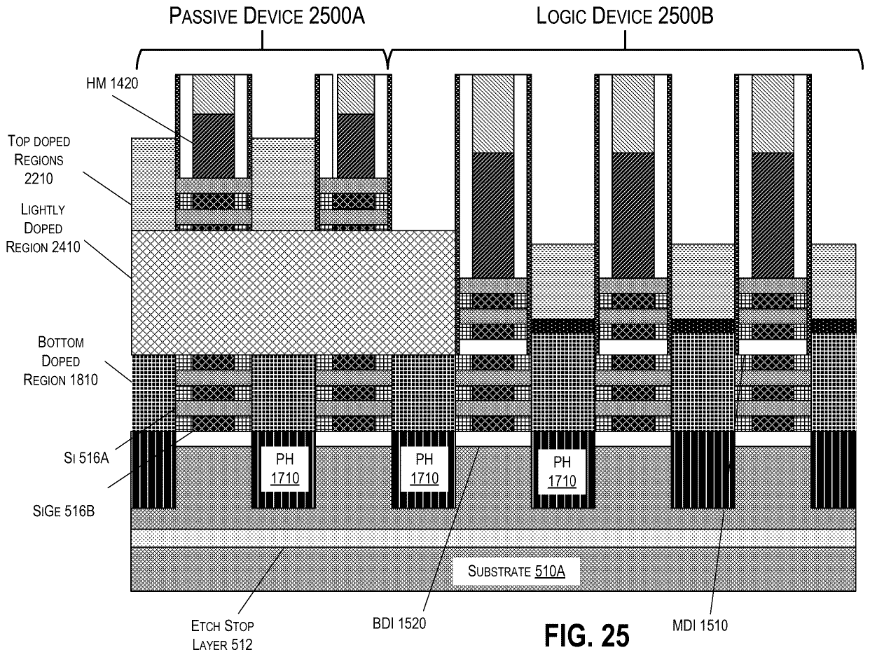

FIG. 25 illustrates the semiconductor device after the formation of the top doped regions, in accordance with some embodiments. In some embodiments, the liner is removed from the stacks of dummy gates 1410 and HM 1420 and the top doped regions 2210 are formed in the passive device 2500A and the logic device 2500B, respectively.

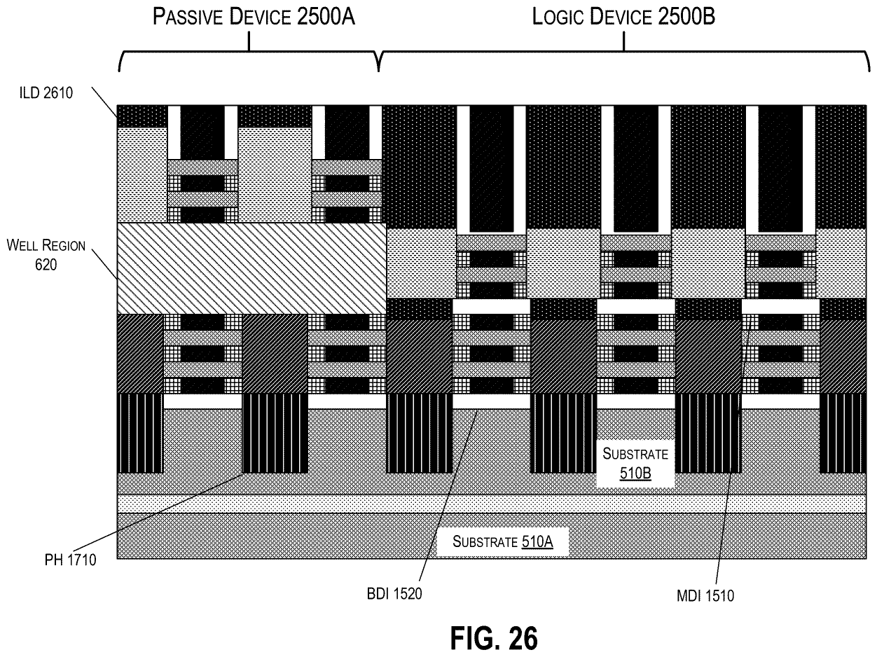

FIG. 26 illustrates the semiconductor device after the formation of the interlayer dielectric, in accordance with some embodiments. In some embodiments, an ILD 2610 is formed over the top doped regions 2210 and top source/drain regions.

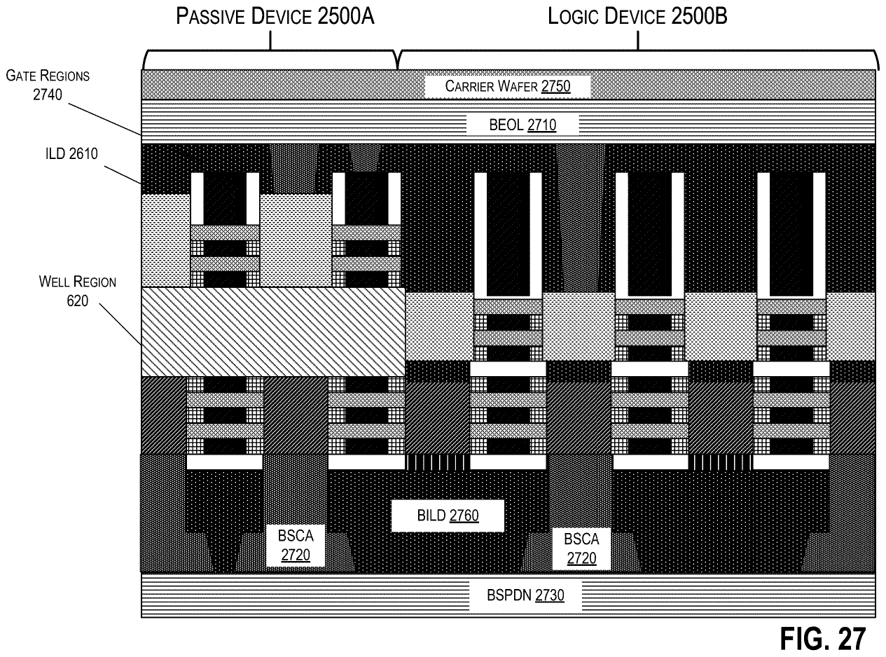

FIG. 27 illustrates the semiconductor device after the middle of line processes, and the back end of line processes, in accordance with some embodiments. In some embodiments, the middle of line is performed. The back end of line, BEOL 2710, the BSCA 2720, the backside ILD, BILD 2760, and the backside power delivery network, BSPDN 2730, are formed. In some embodiments, the gate regions 2740 can be formed by a replacement metal gate (RMG) process to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability.

In various embodiments, carrier wafer bonding, also known as wafer-to-wafer bonding or chip-to-wafer bonding, is performed to join two semiconductor devices together by creating a permanent bond between them via a carrier wafer 2750. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or at elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

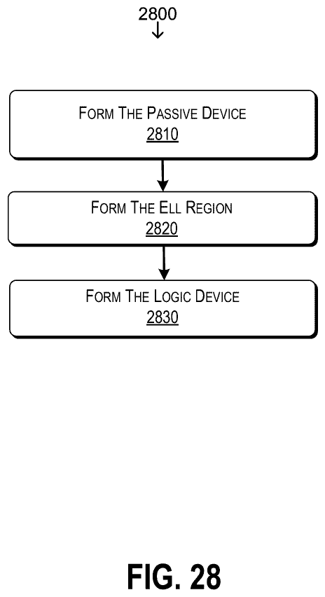

FIG. 28 illustrates a block diagram of a method 2800 for forming the semiconductor device, in accordance with some embodiments. As shown by block 2810, a passive device is formed.

As shown by block 2820, a well region is formed.

As shown by block 2830, a logic device is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the embodiments described. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a passive device, comprising:
a top portion comprising:
a first top doped region and a second top doped region laterally separated by a top gate region; and
a frontside contact over at least one of the first top doped region and the second top doped region; and
a bottom portion comprising:
a first bottom doped region and second bottom doped region laterally separated by a bottom gate region; and
a first backside contact and a second backside contact below the first bottom doped region and the second bottom doped region, respectively; and
a well region electrically connecting the top portion to the bottom portion; and
a logic device adjacent to the passive device and comprising a middle dielectric isolation (MDI) between a top source/drain region and a bottom source/drain region, wherein a thickness of the well region is greater than a thickness of the MDI.

2. The semiconductor device of claim 1, wherein each of the top portion and the bottom portion further comprises a set of nanosheet channels extended horizontally across a gate.

3. The semiconductor device of claim 1, wherein the semiconductor device is an electrostatic discharge device (ESD).

4. The semiconductor device of claim 1, wherein the first top doped region and the second top doped region are doped with an N-type dopant, and the first bottom doped region and the second bottom doped region are doped with a P-type dopant.

5. The semiconductor device of claim 1, wherein the first top doped region and the second top doped region are doped with a P-type dopant, and the first bottom doped region and the second bottom doped region are doped with an N-type dopant.

6. The semiconductor device of claim 1, further comprising:
a back end of line (BEOL) over the passive device and the logic device; and
a carrier wafer over the BEOL.

7. The semiconductor device of claim 1, wherein the semiconductor device is a laterally extended P+ doped region/P-well/N+ doped region diode or a P+ doped region/N-well/N+ doped region diode.

8. The semiconductor device of claim 1, wherein the semiconductor device is a laterally extended NPN bipolar junction with P-well contact, or a PNP bipolar junction with N-well contact.

9. The semiconductor device of claim 1, wherein the well region is a silicon region doped with a P-type dopant or an N-type dopant.

10. The semiconductor device of claim 1, wherein the logic device further comprises a top logic gate region and a bottom logic gate region isolated by the MDI.

11. The semiconductor device of claim 1, wherein the first bottom doped region and the second bottom doped region are aligned at a same vertical height as the bottom source/drain region.

12. The semiconductor device of claim 1, further comprising:
a gate contact over the top gate region; and
an interlayer dielectric over the passive device and the logic device.

13. The semiconductor device of claim 1, wherein the logic device further comprises a top logic portion and a bottom logic portion, wherein the top logic portion comprises the top source/drain region; and wherein the bottom logic portion comprises the bottom source/drain region.

14. The semiconductor device of claim 13, wherein the top logic portion further comprises a frontside via connecting the top source/drain region to a frontside of the semiconductor device.

15. The semiconductor device of claim 13, wherein at least one of the top logic portion and the bottom logic portion is a transistor.

16. The semiconductor device of claim 15, wherein the top logic portion and the bottom logic portion are field-effect transistors (FET).

17. A method for fabrication of a semiconductor device, the method comprising:
forming a passive device, comprising:
forming a top portion comprising:
forming a first top doped region and a second top doped region laterally separated by a top gate region; and
forming a frontside contact over at least one of the first top doped region and the second top doped region; and
forming a bottom portion comprising:
forming a first bottom doped region and second bottom doped region laterally separated by a bottom gate region; and
forming a first backside contact and a second backside contact below the first bottom doped region and the second bottom doped region, respectively; and
forming a well region electrically connecting the top portion to the bottom portion; and
forming a logic device adjacent to the passive device and comprising a middle dielectric isolation (MDI) between a top source/drain region and a bottom source/drain region, wherein a thickness of the well region is greater than a thickness of the MDI.

18. A semiconductor device, comprising:
a passive device, comprising a top device and a bottom device stacked over the top device, and a well region electrically connecting the top device to the bottom device; and
a logic device, comprising a top transistor and a bottom transistor stacked over the top transistor, wherein a thickness of a dielectric isolation layer between the top transistor and the bottom transistor is less than a thickness of the well region.

19. The semiconductor device of claim 18, wherein each of the passive device and the logic device further comprises a set of nanosheet channels extended horizontally across a gate.

20. The semiconductor device of claim 18, further comprising:
a back end of line (BEOL) over the top device and the top transistor; and
a carrier wafer over the BEOL.
